(19) United States
(12) Patent Application Publication
(10) Pub. No.: US 2025/0239996 A1
(43) Pub. Date: Jul. 24, 2025

(54) DUPLEXER

(71) Applicant: WISOL CO., LTD., Gyeonggi-do (KR)

(72) Inventor: Jin Hong JEONG, Gyeonggi-do (KR)

(21) Appl. No.: 19/020,046

(22) Filed: Jan. 14, 2025

(30) Foreign Application Priority Data
Jan. 18, 2024 (KR) 10-2024-0007910

(51) Int. Cl. H03H 9/72; H03H 9/64

(52) U.S. Cl. CPC H03H 9/725; H03H 9/6483

(57) ABSTRACT

Provided is a duplexer connected to an antenna to receive and transmit signals in different frequency bands, the duplexer comprising a receiving filter and a transmission filter, wherein the receiving filter filters a low-frequency band of the same band being used and the transmission filter filters a high-frequency band of the same band, wherein the receiving filter comprises at least two or more series resonators connected in series; and two or more parallel resonators connected in parallel, respectively, to the series resonators, a first parallel resonator and a second parallel resonator, which constitute the parallel resonators, are sequentially connected closest to the antenna, and the second parallel resonator has a relatively higher resonant frequency than the first parallel resonator.

### CROSS-REFERENCE TO RELATED APPLICATION

This application claims priority from Korean Patent Application No. 10-2024-0007910 filed on Jan. 18, 2024 in the Korean Intellectual Property Office, the contents of which in its entirety are herein incorporated by reference.

### FIELD

The present invention relates to a duplexer including a plurality of filters, which are connected to an antenna and configured to pass signals in different frequency bands.

### BACKGROUND

Currently, mobile communication terminals are trending toward incorporating multiband and multimode communication capabilities. Accordingly, radio frequency (RF) front-end modules are necessarily equipped with duplexers.

A duplexer is typically connected to an antenna and includes a plurality of filters that pass signals in different frequency bands. These filters consist of a receiving filter and a transmission filter.

In general, conventional duplexers are designed such that the transmission filter filters a low-frequency band, while the receiving filter filters a high-frequency band. However, there are also duplexers where the transmission filter filters a high-frequency band, and the receiving filter filters a low-frequency band (e.g., B13, B20, etc.).

In the case of a duplexer in which a transmission filter filters a high-frequency band and a receiving filter filters a low-frequency band, there is a need to improve the isolation of the receiving filter and the attenuation (ATT) in the high-frequency band. However, in such a receiving filter, the transmission filter is positioned in the high-frequency band, making it challenging to improve the ATT of the transmission filter.

### SUMMARY

Aspects of the present invention relate to a duplexer that improves the ATT level for a high-frequency band of a receiving filter by selectively controlling the Q value for anti-resonance.

According to one aspect of the present invention, there is provided a duplexer connected to an antenna to transmit and receive signals in different frequency bands, the duplexer comprising a receiving filter and a transmission filter, wherein the receiving filter filters a low-frequency band of the same band being used and the transmission filter filters a high-frequency band of the same band, wherein the receiving filter comprises at least two or more series resonators connected in series; and two or more parallel resonators connected in parallel, respectively, to the series resonators, a first parallel resonator and a second parallel resonator, which constitute the parallel resonators, are sequentially connected closest to the antenna, and the second parallel resonator has a relatively higher resonant frequency than the first parallel resonator.

A first series resonator and a second series resonator, which constitute the series resonators, may be sequentially connected closest to the antenna, and the first parallel resonator may be connected at a junction between the first series resonator and the second series resonator and may have a lower resonant frequency than the first series resonator.

The second parallel resonator may include a reflector, a wavelength of the reflector satisfying the following equation:

$${L}_{Ref} \leq 0.965 \times {L}_{IDT} \qquad [ Equation ]$$

wherein L_{Ref} denotes a wavelength of the reflector and L_{IDT} denotes a wavelength corresponding to a central position of the second parallel resonator.

The second parallel resonator may have a relatively smaller capacitance compared to the first parallel resonator.

### Effects of the Invention

According to the present invention described above, in a duplexer with a receiving filter that filters a low-frequency band, the receiving filter includes a first parallel resonator and a second parallel resonator connected in parallel, respectively, to the first series resonator and the second series resonator. By setting the wavelength of a reflector constituting the second parallel resonator to be no more than 0.965 times the wavelength corresponding to the central position of the second parallel resonator, the Q factor for anti-resonance can be selectively adjusted, and the attenuation (ATT) level in the high-frequency band of the receiving filter can be improved to a certain level or higher.

### BRIEF DESCRIPTION OF THE DRAWINGS

FIG. 1 is a circuit diagram of a duplexer 100 according to one embodiment of the present invention.

FIG. 2 is a graph showing the changes in the Q value for an anti-resonance frequency based on the wavelength of a reflector.

FIG. 3 is a graph comparing the characteristics of the anti-resonance frequency according to the present invention.

### DETAILED DESCRIPTION

The terms used herein are to explain particular embodiments and not intended to limit the present invention. As used herein, singular forms, unless contextually defined otherwise, may include plural forms.

It should be understood that the terms “comprise,” “include,” or “have” used in the various embodiments of the present invention are to indicate the presence of features, numbers, operations, elements, parts, or a combination thereof described in the specifications, and do not preclude the presence or addition of one or more other features, numbers, operations, elements, parts, or a combination thereof.

Although “a first”, “a second”, and the like are used for describing various elements or constituent elements, but the elements or the constituent elements are not limited by the terms. The terms are used for discriminating one element or constituent element from another element or constituent element. Accordingly, a first element or constituent element mentioned below may also be a second element or constituent element within the technical spirit of the present invention as a matter of course.

Additionally, the exemplary embodiments in the detailed description are described with reference to cross-sectional views and/or plan views that illustrate ideal exemplary views of the present invention. Therefore, the embodiments of the present invention are not limited to the specific shapes illustrated in the exemplary views, but may include changes in shapes that may be needed. Thus, the regions illustrated in the figures are schematic in nature and their shapes are not intended to limit the scope of example embodiments.

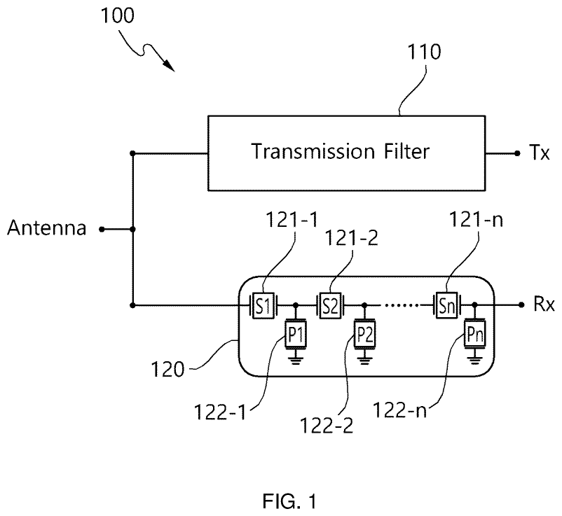

FIG. 1 is a circuit diagram of a duplexer 100 according to an embodiment of the present invention.

A duplexer 100 according to an embodiment of the present invention is connected to an antenna and passes signals in different frequency bands.

Referring to FIG. 1, a duplexer 100 according to the present embodiment includes a transmission filter 110 and a receiving filter 120 that are connected to an antenna and pass signals in different frequency bands.

The duplexer 100 may include an impedance matching element. The impedance matching element may include an inductor and/or a capacitor depending on the impedance to be matched, and it may transmit the maximum power signal through impedance matching. The impedance matching element may be connected between the antenna and ground, or alternatively, or additionally, it may be connected between the antenna and each of the filters to match the impedance.

In the present invention, an LC filter or a SAW filter may be used as the transmission filter 110 and the receiving filter 120. LC filters are suitable for implementing wide pass bands, but they have limitations in improving skirt characteristics. On the other hand, SAW filters, due to their characteristics, are less capable of implementing wide pass bands compared to LC filters but have the advantage of better skirt characteristics. The skirt characteristic refers to how well the pass band and the stop band are distinguished. Good skirt characteristics mean that the slope of the transition band between the pass band and the stop band is steep. Therefore, if an LC filter and an SAW filter are used together by considering the pass bandwidth and the spacing between pass bands, as required by each filter, it is possible to utilize the advantages of both the LC filter and SAW filter.

For example, an LC filter may be used for a frequency band with a relatively wide pass bandwidth, while a SAW filter may be used for a frequency band with a relatively narrow pass bandwidth. Additionally, if the spacing between two adjacent pass bands is large, an LC filter may be used, and if the spacing between two adjacent pass bands is small, a SAW filter may be used for either or both of the transmission filter and the receiving filter.

The transmission filter 110 shown in FIG. 1 filters a high-frequency band, and the receiving filter 120 filters a low-frequency band. For example, if the transmission filter 110 filters the high-frequency band of 777 MHz to 787 MHz, the receiving filter 120 may filter the relatively low-frequency band of 748 MHz to 758 MHz.

The following description focuses on the receiving filter 120, which is a key feature of the present invention.

The receiving filter 120 is based on two pairs of ladder-type structures and may include a double mode SAW (DMS) filter, or it may not include a DMS filter.

The receiving filter 120 may consist of at least two or more series resonators 121-1, 121-2, . . . , and 121-n and parallel resonators 122-1, 122-2, . . . , and 122-n.

The series resonators include a first series resonator 121-1 and a second series resonator 121-2, while the parallel resonators include a first parallel resonator 122-1 and a second parallel resonator 122-2.

The first series resonator 121-1 is connected in series to the second series resonator 121-2. Here, the first series resonator 121-1 and the second series resonator 121-2 are sequentially connected closest to the antenna. Specifically, the first series resonator 121-1 is connected closest to the antenna, and the second series resonator 121-2 is connected in series to the first series resonator 121-1.

The first parallel resonator 122-1 is connected in parallel to the second parallel resonator. Here, the first parallel resonator 122-1 and the second parallel resonator 122-2 are sequentially connected closest to the antenna. Specifically, the first parallel resonator 122-1 is connected closest to the antenna, and the second parallel resonator 122-2 is connected in parallel adjacent to the first parallel resonator 122-1.

The first parallel resonator 122-1 is connected at a junction between the first series resonator 121-1 and the second series resonator 121-2. The first parallel resonator 122-1 may have a lower resonant frequency than the first series resonator 121-1.

The second parallel resonator 122-2 is connected at a junction between the second series resonator 121-2 and another series resonator adjacent to the second series resonator 121-2.

In this case, the second parallel resonator 122-2 may have a higher resonant frequency compared to the first parallel resonator 122-1 or other parallel resonators. Additionally, the second parallel resonator 122-2 may have a relatively smaller capacitance than the first parallel resonator 122-1 or other parallel resonators.

The second parallel resonator 122-2 includes a reflector. The second parallel resonator 122-2 may include at least four pairs of reflectors on each side.

At this time, the wavelength of the reflector included in the second parallel resonator 122-2 may be no more than 0.965 times the wavelength corresponding to the central position of the second parallel resonator 122-2.

In other words, the reflector wavelength of the second parallel resonator 122-2 may satisfy the following equation:

$${L}_{Ref} \leq 0.965 \times {L}_{IDT} \qquad [ Equation ]$$

Here, L_{Ref} denotes the wavelength of the reflector, and L_{IDT} denotes the wavelength corresponding to the central position of the second parallel resonator 122-2.

When applying the second parallel resonator 122-2, there may be an issue where the level at the anti-resonance point increases. To address this issue, the level at the anti-resonance point may be mitigated by adjusting the periodicity ratio of the reflector in the second parallel resonator 122-2.

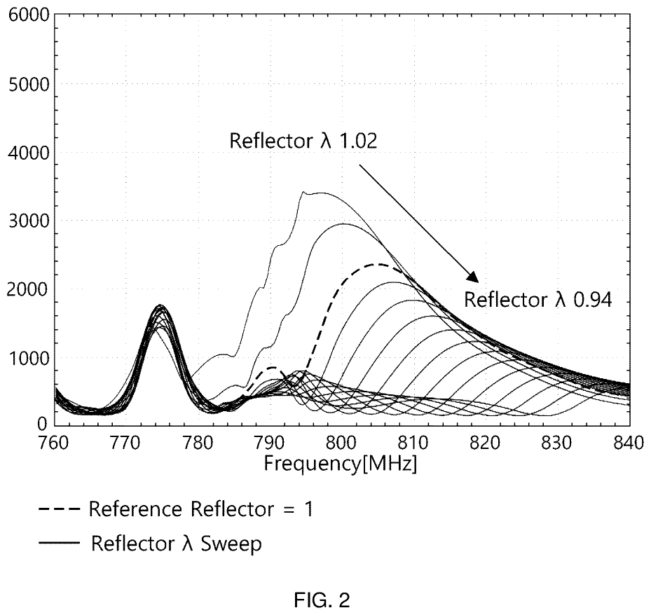

FIG. 2 is a graph showing the changes in the Q value for an anti-resonance frequency based on the wavelength of a reflector.

The wavelength A of the reflector is calculated as a multiple of the wavelength of a main IDT It can be observed that as the reflector is reduced, the Q value at the anti-resonance point decreases. Consequently, it is confirmed that the Q value in the targeted 800 MHz band decreases as well.

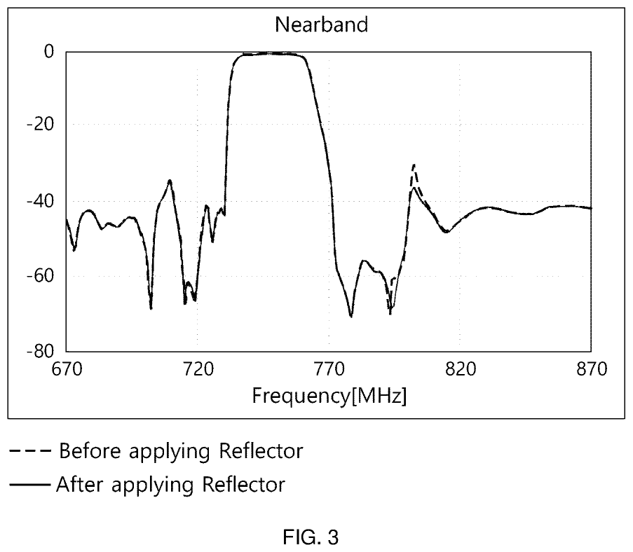

FIG. 3 is a graph comparing the characteristics of the anti-resonance frequency according to the present invention. Referring to FIG. 3, by setting the reflector wavelength of the second parallel resonator 122-2 to be no more than 0.965 times the wavelength corresponding to the central position, the Q value of the anti-resonance may be selectively adjusted, and the attenuation (ATT) level for the high-frequency band of the receiving filter may be improved by 6 dB or more.

The exemplary embodiments of the present invention have been described above. It should be understood by one of ordinary skill in the art that the present invention may be implemented as a modified form without departing from the essential features of the present invention. Therefore, the disclosed embodiments should be considered in a descriptive aspect not a limitative aspect. The scope of the present invention will be shown in the claims not in the foregoing description, and all differences within an equivalent scope thereof should be construed as being included in the present invention.

What is claimed is:

1. A duplexer connected to an antenna to receive and transmit signals in different frequency bands, the duplexer comprising:
a receiving filter; and
a transmission filter,
wherein the receiving filter filters a low-frequency band of the same band being used and the transmission filter filters a high-frequency band of the same band,
wherein the receiving filter comprises at least two or more series resonators connected in series; and
two or more parallel resonators connected in parallel, respectively, to the series resonators,
a first parallel resonator and a second parallel resonator, which constitute the parallel resonators, are sequentially connected closest to the antenna, and
the second parallel resonator has a relatively higher resonant frequency than the first parallel resonator.

2. The piezoelectric thin film filter of claim 1, wherein a first series resonator and a second series resonator, which constitute the series resonators, are sequentially connected closest to the antenna, and
the first parallel resonator is connected at a junction between the first series resonator and the second series resonator, and has a lower resonant frequency than the first series resonator.

3. The piezoelectric thin film filter of claim 1, wherein the second parallel resonator comprises a reflector, a wavelength of the reflector satisfying the following equation:
$${L}_{Ref} \leq 0.965 \times {L}_{IDT} \qquad [ Equation ]$$
wherein L_{Ref} denotes a wavelength of the reflector and L_{IDT} denotes a wavelength corresponding to a central position of the second parallel resonator.

4. The piezoelectric thin film filter of claim 1, wherein the second parallel resonator has a relatively smaller capacitance compared to the first parallel resonator.
